(19) United States
(12) Patent Application Publication
(10) Pub. No.: US 2025/0176370 A1
(43) Pub. Date: May 29, 2025

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: KYEONGSEO MIN, YONGIN-SI (KR); JAEKWON HWANG, YONGIN-SI (KR)

(21) Appl. No.: 18/958,883

(22) Filed: Nov. 25, 2024

(30) Foreign Application Priority Data
Nov. 27, 2023 (KR) 10-2023-0166993

(51) Int. Cl. H10K 59/122; H10K 59/123; H10K 59/124

(52) U.S. Cl. CPC H10K 59/122; H10K 59/123; H10K 59/124

(57) ABSTRACT

A display device includes pixel electrodes disposed in a first direction and a second direction crossing the first direction, a pixel defining layer disposed on the pixel electrodes, exposing a central portion of each of the pixel electrodes, covering a peripheral portion of each of the pixel electrodes, and including first pixel defining layers extending in the first direction and spaced apart from each other in the second direction and second pixel defining layers extending in the second direction and spaced apart from each other in the first direction, and a spacer disposed between two second pixel defining layers disposed adjacent to each other in the first direction among the second pixel defining layers and between two pixel electrodes disposed adjacent to each other in the second direction among the pixel electrodes.

### CROSS-REFERENCE TO RELATED APPLICATIONS

This application claims priority under 35 U.S.C. § 119 to Korean Patent Application No. 10-2023-0166993, filed on Nov. 27, 2023, the disclosure of which is incorporated by reference herein in its entirety.

### TECHNICAL FIELD

Embodiments of the present invention relate to a display device and an electronic device.

### DISCUSSION OF RELATED ART

Flat panel display devices are replacing cathode ray tube display devices as commonly used display devices due to their lightweight and thinness characteristics. Representative examples of a flat panel display include a liquid crystal display (LCD) and an organic light emitting display (OLED).

A flat panel display device includes a display area in which an image is displayed. The display area includes emission areas emitting light and non-emission area disposed around the emission areas. Light emitting elements are disposed in the emission areas, and structures such as, e.g., a spacer, are disposed in the non-emission area.

### SUMMARY

Embodiments of the present invention provide a display device with improved display quality.

Embodiments also provide an electronic device including the display device.

According to an embodiment, a display device includes a plurality of thin film transistors, an insulating layer disposed on the thin film transistors and including an organic insulating material, a plurality of pixel electrodes disposed on the insulating layer, respectively electrically connected to the thin film transistors, and disposed in a first direction and a second direction crossing the first direction, and a pixel defining layer disposed on the insulating layer and the pixel electrodes, exposing a central portion of each of the pixel electrodes, and covering a peripheral portion of each of the pixel electrodes. The pixel defining layer includes a plurality of first pixel defining layers extending in the first direction and spaced apart from each other in the second direction and a plurality of second pixel defining layers extending in the second direction and spaced apart from each other in the first direction. The display device further includes a spacer disposed on the insulating layer and disposed between two second pixel defining layers disposed adjacent to each other in the first direction among the second pixel defining layers and between two pixel electrodes disposed adjacent to each other in the second direction among the pixel electrodes.

In an embodiment, in a plan view, the spacer is spaced apart from each of the second pixel defining layers.

In an embodiment, in a plan view, the spacer is positioned inside one first pixel defining layer among the first pixel defining layers.

In an embodiment, an outer side surface of the spacer contacts an inner side surface of the one first pixel defining layers.

In an embodiment, a lower surface of the spacer and a lower surface of each of the first pixel defining layers contacts an upper surface of the insulating layer.

In an embodiment, a distance between an upper surface of the insulating layer and an upper surface of the spacer is greater than a distance between the upper surface of the insulating layer and an upper surface of each of the second pixel defining layers.

In an embodiment, the display device further includes a plurality of emission layers disposed on the pixel electrodes, extending in the second direction, and spaced apart from each other in the first direction, and a common electrode disposed on the pixel electrodes, the pixel defining layer, and the emission layers. Each of the emission layers is disposed between two second pixel defining layers disposed adjacent to each other in the first direction.

In an embodiment, the emission layers include a first emission layer, a second emission layer, and a third emission layer. The first emission layer, the second emission layer, and the third emission layer emit light of different colors and are sequentially arranged in the first direction.

In an embodiment, in a plan view, the spacer is positioned inside one emission layer among the emission layers.

In an embodiment, an outer side surface of the spacer contacts an inner side surface of the one emission layer.

In an embodiment, the display device further includes an auxiliary electrode disposed under the insulating layer and overlapping one first pixel defining layer among the first pixel defining layers. The common electrode is electrically connected to the auxiliary electrode through a contact hole penetrating the insulating layer and the one first pixel defining layer.

In an embodiment, the display device further includes a first dam disposed on the one first pixel defining layer and surrounding the contact hole in a plan view.

In an embodiment, in the plan view, the first dam is positioned inside one emission layer among the emission layers. In the plan view, the one emission layer is disposed outside the first dam and is not disposed inside the first dam.

In an embodiment, an outer side surface of the first dam contacts an inner side surface of the one emission layer.

In an embodiment, in the plan view, the first dam is spaced apart from the spacer with at least one pixel electrode among the pixel electrodes or at least one second pixel defining layer among the second pixel defining layers interposed therebetween.

In an embodiment, a through hole is defined that penetrates one first pixel defining layer among the first pixel defining layers and exposes an upper surface of the insulating layer. The display device further includes a second dam disposed on the one first pixel defining layer and surrounding the through hole in the plan view.

In an embodiment, in the plan view, the second dam is spaced apart from the spacer with at least one pixel electrode among the pixel electrodes or at least one second pixel defining layer among the second pixel defining layers interposed therebetween.

According to an embodiment, a display device includes a plurality of thin film transistors, an insulating layer disposed on the thin film transistors and including an organic insulating material, a plurality of pixel electrodes disposed on the insulating layer, respectively electrically connected to the thin film transistors, and disposed in a first direction and a second direction crossing the first direction, and a pixel defining layer disposed on the insulating layer and the pixel electrodes, exposing a central portion of each of the pixel electrodes, and covering a peripheral portion of each of the pixel electrodes. The pixel defining layer includes a plurality of first pixel defining layers extending in the first direction and spaced apart from each other in the second direction and a plurality of second pixel defining layers extending in the second direction and spaced apart from each other in the first direction. The display device further includes an auxiliary electrode disposed under the insulating layer and overlapping one first pixel defining layer among the first pixel defining layers, a plurality of emission layers disposed on the pixel electrodes, extending in the second direction, and spaced apart from each other in the first direction, and a common electrode disposed on the pixel electrodes, the pixel defining layer, and the emission layers and electrically connected to the auxiliary electrode through a contact hole penetrating the insulating layer and the one first pixel defining layer.

In an embodiment, the display device further includes a dam disposed on the one first pixel defining layer and surrounding the contact hole in a plan view.

According to an embodiment, a display device includes a plurality of thin film transistors, an insulating layer disposed on the thin film transistors and including an organic insulating material, a plurality of pixel electrodes disposed on the insulating layer, respectively electrically connected to the thin film transistors, and disposed in a first direction and a second direction crossing the first direction, and a pixel defining layer disposed on the insulating layer and the pixel electrodes, exposing a central portion of each of the pixel electrodes, and covering a peripheral portion of each of the pixel electrodes. The pixel defining layer includes a plurality of first pixel defining layers extending in the first direction and spaced apart from each other in the second direction and a plurality of second pixel defining layers extending in the second direction and spaced apart from each other in the first direction. The display device further includes a dam disposed on one first pixel defining layer among the first pixel defining layers and surrounding a through hole in a plan view, the through hole penetrating the one first pixel defining layer and exposing an upper surface of the insulating layer.

According to an embodiment, an electronic device includes a display device and a power supply configured to provide power to the display device. The display device includes a plurality of thin film transistors, an insulating layer disposed on the thin film transistors and including an organic insulating material, a plurality of pixel electrodes disposed on the insulating layer, respectively electrically connected to the thin film transistors, and disposed in a first direction and a second direction crossing the first direction, and a pixel defining layer disposed on the insulating layer and the pixel electrodes, exposing a central portion of each of the pixel electrodes, and covering a peripheral portion of each of the pixel electrodes. The pixel defining layer includes a plurality of first pixel defining layers extending in the first direction and spaced apart from each other in the second direction and a plurality of second pixel defining layers extending in the second direction and spaced apart from each other in the first direction. The display device further includes a spacer disposed on the insulating layer and disposed between two second pixel defining layers disposed adjacent to each other in the first direction among the second pixel defining layers and between two pixel electrodes disposed adjacent to each other in the second direction among the pixel electrodes.

The display device according to embodiments of the present invention may include the pixel defining layer defining the emission areas and the non-emission area. The pixel defining layer may include the first pixel defining layer extending in one direction and the second pixel defining layer crossing the first pixel defining layer. A structure such as a spacer disposed in the non-emission area may overlap the first pixel defining layer and does not overlap the second pixel defining layer. Accordingly, a width of the second pixel defining layer may be reduced, and a display device having high resolution and improved display quality may be implemented.

### BRIEF DESCRIPTION OF THE DRAWINGS

The above and other features of the present invention will become more apparent by describing in detail embodiments thereof with reference to the accompanying drawings.

FIG. 1 is a plan view illustrating a display device according to an embodiment.

FIG. 2 is a plan view illustrating a pixel included in the display device of FIG. 1.

FIG. 3 is a cross-sectional view taken along line I-I′ of FIG. 2.

FIG. 4 is a cross-sectional view taken along line II-II′ of FIG. 2.

FIG. 5 is a cross-sectional view taken along line III-III′ of FIG. 2.

FIG. 6 is a cross-sectional view taken along line IV-IV′ of FIG. 2.

FIG. 7 is a cross-sectional view taken along line V-V′ of FIG. 2.

FIGS. 8 to 18 are cross-sectional views illustrating a method of manufacturing a display device according to an embodiment.

FIG. 19 is a block diagram illustrating an electronic device according to an embodiment.

### DETAILED DESCRIPTION

Embodiments of the present invention will be described more fully hereinafter with reference to the accompanying drawings. Like reference numerals may refer to like elements throughout the accompanying drawings.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, a reference number may indicate a singular element or a plurality of the element. For example, a reference number labeling a singular form of an element within the drawing figures may be used to reference a plurality of the singular element within the text of specification.

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

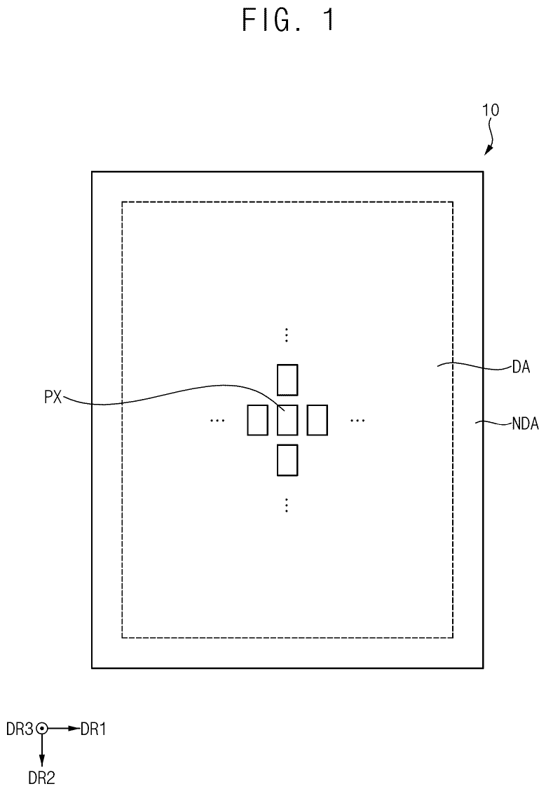

FIG. 1 is a plan view illustrating a display device according to an embodiment.

Referring to FIG. 1, in an embodiment, a display device 10 may have a display surface defined by a first direction DR1 and a second direction DR2 crossing the first direction DR1. The display device 10 may display an image in a third direction DR3 through the display surface. For example, the second direction DR2 may be substantially perpendicular to the first direction DR1. The third direction DR3 may be substantially parallel to a normal direction of the display surface. The display surface may correspond to a front surface (or an upper surface) of the display device 10.

The display device 10 may include a display area DA and a non-display area NDA. A plurality of pixels PX that generate the image may be disposed in the display area DA.

Each of the pixels PX may include a pixel circuit and a light emitting element. The pixel circuit may include at least one thin film transistor and at least one capacitor. The thin film transistor may generate a driving current and provide the generated driving current to the light emitting element. The light emitting element may emit light based on the driving current. For example, the light emitting element may include an organic light emitting diode, an inorganic light emitting diode, a quantum dot light emitting diode, or the like. The image may be generated by combining light emitted from each of the pixels PX.

The non-display area NDA may be positioned around the display area DA. The non-display area NDA may be positioned outside the display area DA. For example, the non-display area NDA may surround the display area DA in a plan view. The non-display area NDA may entirely or partially surround the display area DA in a plan view.

A driver may be disposed in the non-display area NDA. The driver may provide various driving signals (e.g., a driving voltage, a gate signal, a data signal, or the like) that drive the pixels PX to the display area DA. For example, the driver may include a data driver, a gate driver, or the like.

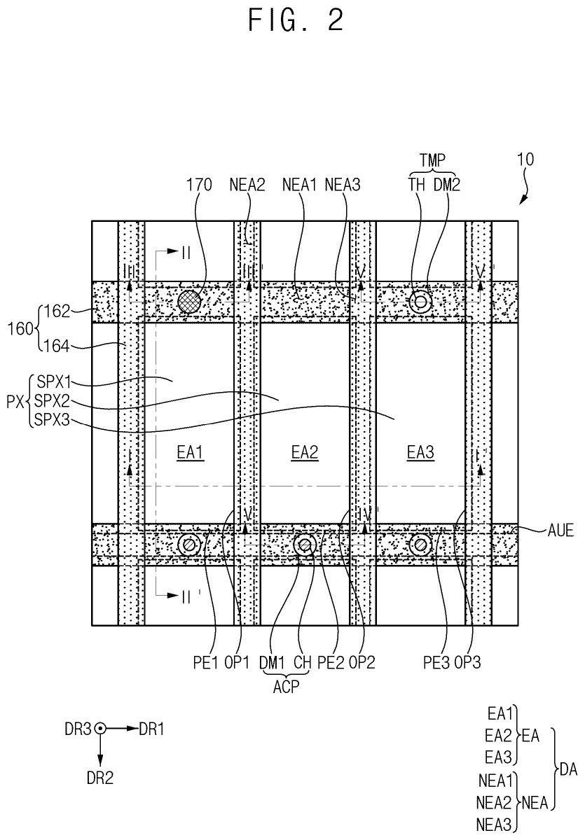

FIG. 2 is a plan view illustrating a pixel included in the display device of FIG. 1.

Referring to FIG. 2, the display area DA may include first to third emission areas EA1, EA2, and EA3 that emit light of different colors and a non-emission area NEA.

The first to third emission areas EA1, EA2, and EA3 are disposed adjacent to each other, and may form one pixel area. The display area DA may include the plurality of pixel areas.

Light of a first color may be emitted from the first emission area EA1, light of a second color may be emitted from the second emission area EA2, and light of a third color may be emitted from the third emission area EA3. A first sub-pixel SPX1 emitting light of the first color may be disposed in the first emission area EA1, a second sub-pixel SPX2 emitting light of the second color may be disposed in the second emission area EA2, and a third sub-pixel SPX3 emitting light of the third color may be disposed in the third emission area EA3. For example, the first color may be red, the second color may be green, and the third color may be blue, but this is an example and embodiments are not limited thereto. The first to third sub-pixels SPX1, SPX2, and SPX3 disposed in one pixel area may form one pixel PX.

In an embodiment, the plurality of pixel areas may be disposed in a matrix form in the first direction DR1 and the second direction DR2 in a plan view. That is, the plurality of pixels PX may be disposed in a matrix form in the first direction DR1 and the second direction DR2 in a plan view. For example, in each of the pixel areas, the first to third emission areas EA1, EA2, and EA3 may be sequentially arranged to be spaced apart from each other in the first direction DR1. That is, in each of the pixel areas, the first to third sub-pixels SPX1, SPX2, and SPX3 may be sequentially arranged to be spaced apart from each other in the first direction DR1. In addition, the plurality of first emission areas EA1 may be arranged to be spaced apart from each other in the second direction DR2, the plurality of second emission areas EA2 may be arranged to be spaced apart from each other in the second direction DR2, and the plurality of third emission areas EA3 may be arranged to be spaced apart from each other in the second direction DR2.

The non-emission area NEA may be an area where light is not emitted. The non-emission area NEA may be disposed adjacent to the first to third emission areas EA1, EA2, and EA3. In an embodiment, the non-emission area NEA may surround each of the first to third emission areas EA1, EA2, and EA3 in a plan view. For example, the non-emission area NEA may have a grid shape in a plan view.

The first to third emission areas EA1, EA2, and EA3 and the non-emission area NEA may be defined by a pixel defining layer 160. The pixel defining layer 160 may define a first pixel opening OP1 exposing a central portion of a first pixel electrode PE1 of the first sub-pixel SPX1, a second pixel opening OP2 exposing a central portion of a second pixel electrode PE2 of the second sub-pixel SPX2, and a third pixel opening OP3 exposing a central portion of a third pixel electrode PE3 of the third sub-pixel SPX3. The pixel defining layer 160 may cover a peripheral portion of each of the first pixel electrode PE1, the second pixel electrode PE2, and the third pixel electrode PE3. For example, the pixel defining layer 160 may have a grid shape in a plan view.

In a plan view, the first emission area EA1 may be defined by the first pixel opening OP1, the second emission area EA2 may be defined by the second pixel opening OP2, and the third emission area EA3 may be defined by the third pixel opening OP3. In a plan view, the non-emission area NEA may be defined as an area where the pixel defining layer 160 is disposed. In other words, the non-emission area NEA may be defined as an area that overlaps the pixel defining layer 160.

In an embodiment, the pixel defining layer 160 may include first pixel defining layers 162 and second pixel defining layers 164. As illustrated in FIG. 2, each of the first pixel defining layers 162 may extend in the first direction DR1, and the first pixel defining layers 162 may be spaced apart from each other in the second direction DR2. For example, each of the first pixel defining layers 162 may extend lengthwise in the first direction DR1, and the first pixel defining layers 162 may be spaced apart from each other in the second direction DR2. Each of the second pixel defining layers 164 may extend in the second direction DR2, and the second pixel defining layers 164 may be spaced apart from each other in the first direction DR1. For example, each of the second pixel defining layers 164 may extend lengthwise in the second direction DR2, and the second pixel defining layers 164 may be spaced apart from each other in the first direction DR1. The first pixel defining layers 162 and the second pixel defining layers 164 may cross each other.

In an embodiment, the non-emission area NEA may include first non-emission areas NEA1, second non-emission areas NEA2, and third non-emission areas NEA3. Each of the first non-emission areas NEA1 may be defined as an area where the first pixel defining layer 162 is disposed and the second pixel defining layer 164 is not disposed. In other words, each of the first non-emission areas NEA1 may be defined as an area that overlaps the first pixel defining layer 162 and does not overlap the second pixel defining layer 164. For example, the first non-emission areas NEA1 may be disposed in a matrix form in the first direction DR1 and the second direction DR2 in a plan view.

Each of the second non-emission areas NEA2 may be defined as an area where the second pixel defining layer 164 is disposed and the first pixel defining layer 162 is not disposed. In other words, each of the second non-emission areas NEA2 may be defined as an area that overlaps the second pixel defining layer 164 and does not overlap the first pixel defining layer 162. For example, the second non-emission areas NEA2 may be disposed in a matrix form in the first direction DR1 and the second direction DR2 in a plan view.

Each of the third non-emission areas NEA3 may be defined as an area where both the first pixel defining layer 162 and the second pixel defining layer 164 are disposed. In other words, each of the third non-emission areas NEA3 may be defined as an area that overlaps both the first pixel defining layer 162 and the second pixel defining layer 164. That is, each of the third non-emission areas NEA3 may be an area where the first pixel defining layer 162 and the second pixel defining layer 164 cross each other. For example, the third non-emission areas NEA3 may be disposed in a matrix form in the first direction DR1 and the second direction DR2 in a plan view.

In an embodiment, structures, such as a spacer 170, an auxiliary electrode contact portion ACP, or a thickness measurement portion TMP, may be disposed in a portion of the first non-emission areas NEA1 of the display area DA. For example, one of the spacer 170, the auxiliary electrode contact portion ACP, and the thickness measurement portion TMP may be disposed in one of the first non-emission areas NEA1, and none of the spacer 170, the auxiliary electrode contact portion ACP, and the thickness measurement portion TMP may be disposed in another one of the first non-emission areas NEA1. In an embodiment, the structures, such as the spacer 170, the auxiliary electrode contact portion ACP, or the thickness measurement portion TMP, are not disposed in the second non-emission areas NEA2 and the third non-emission areas NEA3.

In a comparative example, the structure is disposed in the third non-emission areas NEA3 where the first pixel defining layers 162 and the second pixel defining layers 164 cross each other. In this case, due to a size of the structure, there is a limit to reducing a width of each of the second pixel defining layers 164 in the first direction DR1. That is, it may be difficult to reduce a width of each of the second and third non-emission areas NEA2 and NEA3 in the first direction DR1, and thus, it may be difficult to implement high resolution. However, according to embodiments of the present invention, the structures, such as the spacer 170, the auxiliary electrode contact portion ACP, or the thickness measurement portion TMP, are not disposed in the second and third non-emission areas NEA2 and NEA3 and may be disposed only in the first non-emission areas NEA1. As a result, the width of each of the second and third non-emission areas NEA2 and NEA3 in the first direction DR1 may be reduced. That is, since the structures do not overlap each of the second pixel defining layers 164, the width of each of the second pixel defining layers 164 in the first direction DR1 may be further reduced. Accordingly, a high resolution display device 10 having improved display quality may be implemented according to embodiments of the present invention.

FIG. 2 illustrates that one spacer 170, three auxiliary electrode contact portions ACP, and one thickness measurement portion TMP are disposed to correspond to one pixel area. However, this is an example and embodiments are not limited thereto. For example, the disposition or arrangement of the spacer 170, the auxiliary electrode contact portion ACP, and the thickness measurement portion TMP may be variously modified. For example, one spacer 170 may be disposed to correspond to the plurality of pixel areas. Likewise, one auxiliary electrode contact portion ACP may be disposed to correspond to the plurality of pixel areas, and one thickness measurement portion TMP may be disposed to correspond to the plurality of pixel areas. In addition, FIG. 2 illustrates that the display device 10 includes all of the spacer 170, the auxiliary electrode contact portion ACP, and the thickness measurement portion TMP, but some of the spacer 170, the auxiliary electrode contact portion ACP, and the thickness measurement portion TMP may be omitted according to embodiments. The spacer 170, the auxiliary electrode contact portion ACP, and the thickness measurement portion TMP will be described in further detail below.

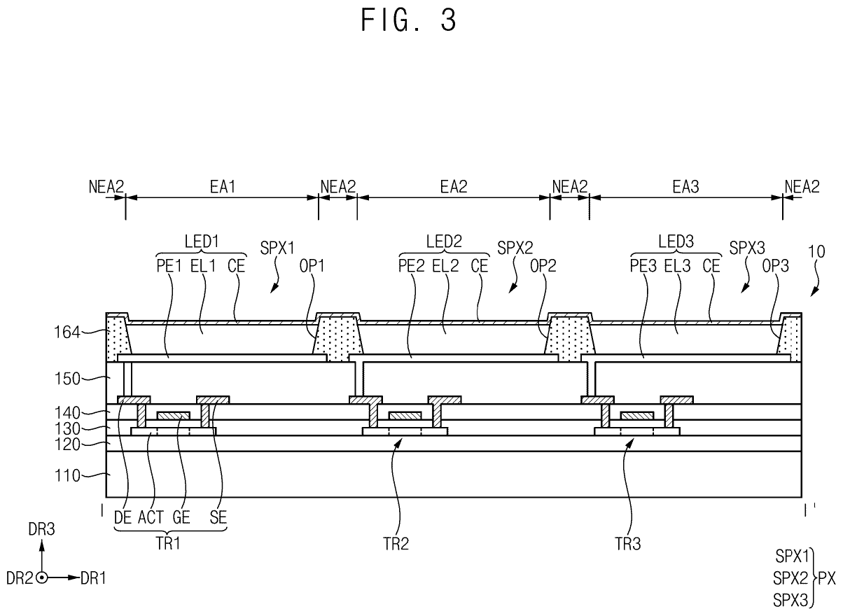

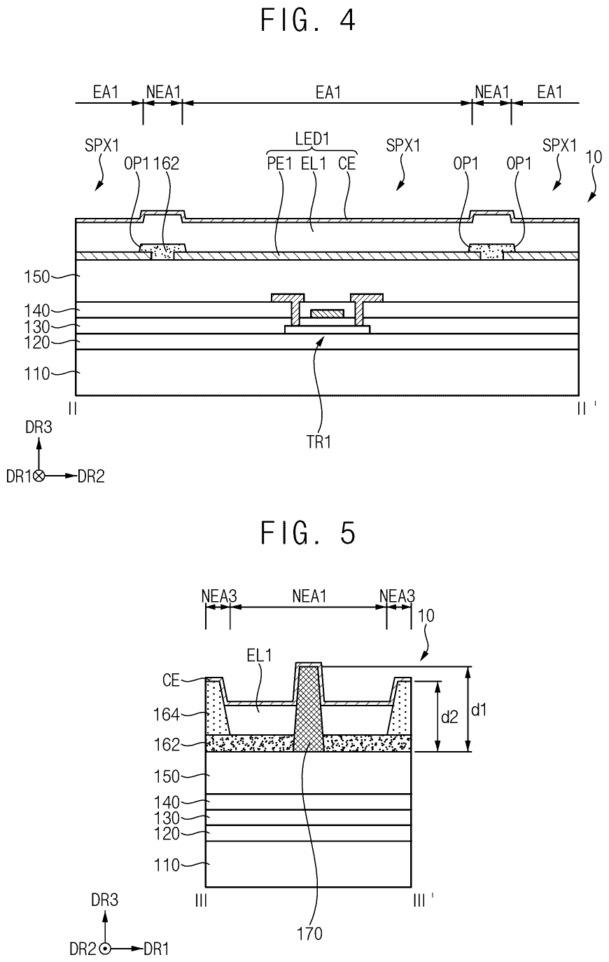

FIG. 3 is a cross-sectional view taken along line I-I′ of FIG. 2. FIG. 4 is a cross-sectional view taken along line II-II′ of FIG. 2.

Hereinafter, the plurality of pixels PX disposed in the plurality of pixel areas included in the display area DA will be described in detail with reference to FIGS. 2 to 4.

Referring to FIGS. 2 to 4, in an embodiment, the display device 10 may include a substrate 110, a buffer layer 120, insulating layers 130, 140, and 150, the pixel defining layer 160, and the plurality of pixels PX. Each of the pixels PX may include the first to third sub-pixels SPX1, SPX2, and SPX3 emitting light of different colors. The first sub-pixel SPX1 may include a first pixel circuit including a first thin film transistor TR1 and a first light emitting element LED1 emitting light of the first color (e.g., red). The second sub-pixel SPX2 may include a second pixel circuit including a second thin film transistor TR2 and a second light emitting element LED2 emitting light of the second color (e.g., green). The third sub-pixel SPX3 may include a third pixel circuit including a third thin film transistor TR3 and a third light emitting element LED3 emitting light of the third color (e.g., blue).

The substrate 110 may be an insulating substrate including or formed of a transparent material or a non-transparent material. In an embodiment, the substrate 110 may be a rigid substrate including a material such as, for example, glass or quartz. In an embodiment, the substrate 110 may be a flexible substrate including plastic.

The buffer layer 120 may be disposed on the substrate 110. The buffer layer 120 may prevent or reduce impurities such as, for example, oxygen or moisture, from penetrating into an upper portion of the substrate 110 through the substrate 110. The buffer layer 120 may include an inorganic material. In an embodiment, for example, the buffer layer 120 may include silicon oxide (SiO), silicon nitride (SiN), silicon oxynitride (SiON), silicon oxycarbide (SiOC), silicon carbonitride (SiCN), aluminum oxide (AlO), aluminum nitride (AlN), tantalum oxide (TaO), hafnium oxide (HfO), zirconium oxide (ZrO), titanium oxide (TiO), or the like, alone or in a combination thereof. The buffer layer 120 may have a single-layered structure or a multi-layered structure including a plurality of insulating layers. In an embodiment, the buffer layer 120 may be omitted.

The first to third thin film transistors TR1, TR2, and TR3 may be disposed on the buffer layer 120. The first thin film transistor TR1 may include an active layer ACT, a gate electrode GE, a source electrode SE, and a drain electrode DE. Each of the second thin film transistor TR2 and the third thin film transistor TR3 may be substantially the same as or similar to the first thin film transistor TR1.

The active layer ACT may be disposed on the buffer layer 120. The active layer ACT may include, for example, an oxide semiconductor, a silicon semiconductor, an organic semiconductor, or the like. In an embodiment, the oxide semiconductor may include at least one of, for example, indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include, for example, an amorphous silicon, a polycrystalline silicon, or the like. The active layer ACT may include a source area, a drain area, and a channel area positioned between the source area and the drain area.

A first insulating layer 130 may be disposed on the active layer ACT. The first insulating layer 130 may cover the active layer ACT on the buffer layer 120. The first insulating layer 130 may include an inorganic insulating material.

The gate electrode GE may be disposed on the first insulating layer 130. The gate electrode GE may overlap the channel area of the active layer ACT. The gate electrode GE may include a conductive material such as, for example, a metal, an alloy, a conductive metal nitride, a conductive metal oxide, a transparent conductive material, or the like. In an embodiment, the gate electrode GE may include, for example, gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), or the like, alone or in a combination thereof. The gate electrode GE may have a single-layered structure or a multi-layered structure including a plurality of conductive layers.

A second insulating layer 140 may be disposed on the gate electrode GE. The second insulating layer 140 may cover the gate electrode GE on the first insulating layer 130. The second insulating layer 140 may include an inorganic insulating material.

The source electrode SE and the drain electrode DE may be disposed on the second insulating layer 140. The source electrode SE and the drain electrode DE may be connected to the source area and the drain area of the active layer ACT, respectively. Each of the source electrode SE and the drain electrode DE may include a conductive material.

A third insulating layer 150 may be disposed on the source electrode SE and the drain electrode DE. The third insulating layer 150 may include an organic insulating material. In an embodiment, the third insulating layer 150 may include, for example, photoresist, polyacryl-based resin, polyimide-based resin, polyamide-based resin, siloxane-based resin, acryl-based resin, epoxy-based resin, or the like, used alone or in a combination thereof.

The first to third pixel electrodes PE1, PE2, and PE3 may be disposed on the third insulating layer 150. The first to third pixel electrodes PE1, PE2, and PE3 may be sequentially spaced apart from each other in the first direction DR1. In addition, the plurality of first pixel electrodes PE1 may be spaced apart from each other in the second direction DR2, the plurality of second pixel electrodes PE2 may be spaced apart from each other in the second direction DR2, and the plurality of third pixel electrodes PE3 may be spaced apart from each other in the second direction DR2. That is, in the display area DA, the plurality of pixel electrodes may be disposed in a matrix form along the first direction DR1 and the second direction DR2.

Each of the first to third pixel electrodes PE1, PE2, and PE3 may include a conductive material. Each of the first to third pixel electrodes PE1, PE2, and PE3 may have a single-layered structure or a multi-layered structure including a plurality of conductive layers.

The first pixel electrode PE1 may overlap the first emission area EA1. The first pixel electrode PE1 may be connected to the drain electrode DE of the first thin film transistor TR1 through a first contact hole formed in the third insulating layer 150.

The second pixel electrode PE2 may overlap the second emission area EA2. The second pixel electrode PE2 may be connected to a drain electrode of the second thin film transistor TR2 through a second contact hole formed in the third insulating layer 150.

The third pixel electrode PE3 may overlap the third emission area EA3. The third pixel electrode PE3 may be connected to a drain electrode of the third thin film transistor TR3 through a third contact hole formed in the third insulating layer 150.

The pixel defining layer 160 may be disposed on the third insulating layer 150 and the first to third pixel electrodes PE1, PE2, and PE3. The pixel defining layer 160 may define the first pixel opening OP1 exposing the central portion of the first pixel electrode PE1, the second pixel opening OP2 exposing the central portion of the second pixel electrode PE2, and the third pixel opening OP3 exposing the central portion of the third pixel electrode PE3. The pixel defining layer 160 may cover the peripheral portion of each of the first to third pixel electrodes PE1, PE2, and PE3.

The pixel defining layer 160 may include the first pixel defining layers 162 and the second pixel defining layers 164. Each of the first pixel defining layers 162 and the second pixel defining layers 164 may include an organic insulating material. In an embodiment, for example, each of the first pixel defining layers 162 and the second pixel defining layers 164 may include a photoresist.

Each of the first pixel defining layers 162 may extend in the first direction DR1, and the first pixel defining layers 162 may be spaced apart from each other in the second direction DR2. Each of the second pixel defining layers 164 may extend in the second direction DR2, and the second pixel defining layers 164 may be spaced apart from each other in the first direction DR1. The first pixel defining layers 162 and the second pixel defining layers 164 may cross each other. The second pixel defining layers 164 may be disposed on the first pixel defining layers 162. A thickness of each of the second pixel defining layers 164 may be greater than a thickness of each of the first pixel defining layers 162. An upper surface of each of the second pixel defining layers 164 may have liquid repellency.

A first emission layer EL1 may be disposed on the first pixel electrode PE1, a second emission layer EL2 may be disposed on the second pixel electrode PE2, and a third emission layer EL3 may be disposed on the third pixel electrode PE3. In an embodiment, the first to third emission layers EL1, EL2, and EL3 may be formed by inkjet printing.

The first emission layer EL1 may be disposed at least in the first pixel opening OP1 of the pixel defining layer 160. In an embodiment, as illustrated in FIG. 4, the first emission layer EL1 may extend in the second direction DR2. In the display area DA, the plurality of first emission layers EL1 each extending in the second direction DR2 may be spaced apart from each other in the first direction DR1. Each of the first emission layers EL1 may overlap the plurality of first emission areas EA1 spaced apart from each other in the second direction DR2. That is, each of the first emission layers EL1 may overlap the plurality of first pixel electrodes PEL spaced apart from each other in the second direction DR2. In addition, each of the first emission layers EL1 may further overlap the first non-emission area NEA1 between two first emission areas EA1 disposed adjacent to each other in the second direction DR2.

The second emission layer EL2 may be disposed at least in the second pixel opening OP2 of the pixel defining layer 160. In an embodiment, the second emission layer EL2 may extend in the second direction DR2. In the display area DA, the plurality of second emission layers EL2 each extending in the second direction DR2 may be spaced apart from each other in the first direction DR1. Each of the second emission layers EL2 may overlap the plurality of second emission areas EA2 spaced apart from each other in the second direction DR2. That is, each of the second emission layers EL2 may overlap the plurality of second pixel electrodes PE2 spaced apart from each other in the second direction DR2. In addition, each of the second emission layers EL2 may further overlap the first non-emission area NEA1 between two second emission areas EA2 disposed adjacent to each other in the second direction DR2.

The third emission layer EL3 may be disposed at least in the third pixel opening OP3 of the pixel defining layer 160. In an embodiment, the third emission layer EL3 may extend in the second direction DR2. In the display area DA, the plurality of third emission layers EL3 each extending in the second direction DR2 may be spaced apart from each other in the first direction DR1. Each of the third emission layers EL3 may overlap the plurality of third emission areas EA3 spaced apart from each other in the second direction DR2. That is, each of the third emission layers EL3 may overlap the plurality of third pixel electrodes PE3 spaced apart from each other in the second direction DR2. In addition, each of the third emission layers EL3 may further overlap the first non-emission area NEA1 between two third emission areas EA3 disposed adjacent to each other in the second direction DR2.

Each of the first to third emission layers EL1, EL2, and EL3 may extend in the second direction DR2, and the first to third emission layers EL1, EL2, and EL3 may be sequentially spaced apart from each other in the first direction DR1. Each of the first to third emission layers EL1, EL2, and EL3 may be disposed between two second pixel defining layers 164 disposed adjacent to each other in the first direction DR1 among the second pixel defining layers 164.

The first emission layer EL1 may include a first emission material emitting light of the first color (e.g., red), the second emission layer EL2 may include a second emission material emitting light of the second color (e.g., green), and the third emission layer EL3 may include a third emission material emitting light of the third color (e.g., blue). In some embodiments, each of the first to third emission materials may include at least one of an organic emission material or quantum dot.

In an embodiment, the organic emission material may include a low molecular organic compound or a high molecular organic compound. Examples of the low molecular organic compound may include copper phthalocyanine, N,N′-diphenylbenzidine, tris-(8-hydroxyquinoline)aluminum, or the like. Examples of the high molecular organic compound may include poly(3,4-ethylenedioxythiophene), polyaniline, poly-phenylenevinylene, polyfluorene, or the like. These can be used alone or in a combination thereof.

In an embodiment, the quantum dot may include a core including, for example, a Group II-VI compound, a Group III-V compound, a Group IV-VI compound, a Group IV element, and/or a Group IV compound. In an embodiment, the quantum dot may have a core-shell structure including the core and a shell surrounding the core. The shell may serve as a protection layer which may prevent the core from being chemically denatured to maintain semiconductor characteristics, and may serve as a charging layer which may impart electrophoretic characteristics to the quantum dot.

A common electrode CE may be disposed on the first to third emission layers EL1, EL2, and EL3. The common electrode CE may also be disposed on the pixel defining layer 160. For example, the common electrode CE may entirely overlap the display area DA. The common electrode CE may include a conductive material.

The first pixel electrode PE1, a portion of the first emission layer EL1, and a portion of the common electrode CE that overlap each other in the first emission area EA1 may form the first light emitting element LED1. The second pixel electrode PE2, a portion of the second emission layer EL2, and a portion of the common electrode CE that overlap each other in the second emission area EA2 may form the second light emitting element LED2. The third pixel electrode PE3, a portion of the third emission layer EL3, and a portion of the common electrode CE that overlap each other in the third emission area EA3 may form the third light emitting element LED3.

According to embodiments, the display device 10 may further include various functional layers, such as, for example, an encapsulation layer, a color filter layer, a touch sensing layer, a polarizing layer, or the like, disposed on the common electrode CE.

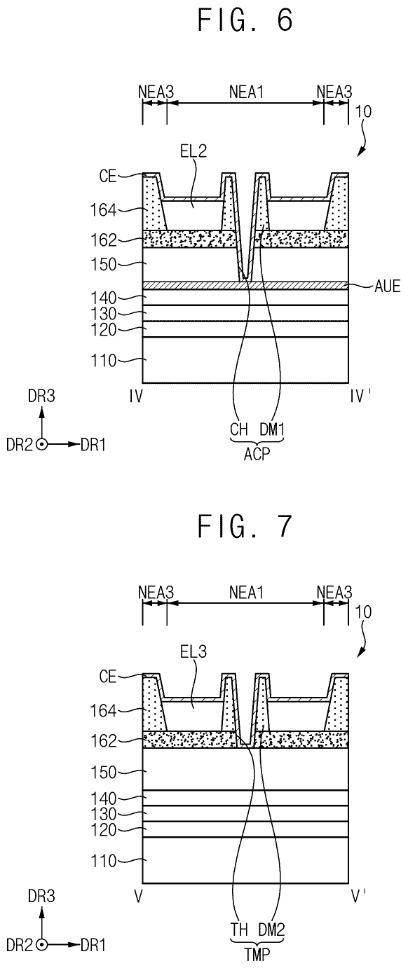

FIG. 5 is a cross-sectional view taken along line III-III′ of FIG. 2. FIG. 6 is a cross-sectional view taken along line IV-IV′ of FIG. 2. FIG. 7 is a cross-sectional view taken along line V-V′ of FIG. 2.

Hereinafter, the structures disposed in the first non-emission areas NEA1 included in the display area DA will be described in detail with reference to FIGS. 2, 5, 6, and 7.

First, referring to FIGS. 2 and 5, in an embodiment, the spacer 170 may be disposed on the third insulating layer 150. The spacer 170 may maintain a gap between a light emitting element layer and various structures (e.g., a color conversion panel, a touch panel, or the like) that may be disposed on top of the light emitting element layer.

The spacer 170 may be disposed in the non-emission area NEA of the display area DA. The spacer 170 may be disposed in some of the first non-emission areas NEA1, and may not be disposed in the second non-emission areas NEA2 and third non-emission areas NEA3. The spacer 170 may include an organic insulating material. In an embodiment, for example, the spacer 170 may include photoresist. Although only one spacer 170 is illustrated in FIG. 2, the plurality of spacers 170 may be provided. In this case, the plurality of spacers 170 may be disposed in different first non-emission areas NEA1, respectively.

As illustrated in FIG. 2, the spacer 170 may be disposed between two second pixel defining layers 164 disposed adjacent to each other in the first direction DR1 and between two pixel electrodes disposed adjacent to each other in the second direction DR2. In a plan view, the spacer 170 may be spaced apart from each of the adjacent second pixel defining layers 164. For example, as illustrated in FIG. 2, the spacer 170 may be disposed between two first pixel electrodes PE1 disposed adjacent to each other in the second direction DR2. In a plan view, the spacer 170 may be spaced apart from each of the adjacent first pixel electrodes PE1. In an embodiment, the spacer 170 may be disposed between two second pixel electrodes PE2 disposed adjacent to each other in the second direction DR2 or between two third pixel electrodes PE3 disposed adjacent to each other in the second direction DR2.

As described above, the first non-emission area NEA1 where the spacer 170 is disposed may be an area where the first pixel defining layer 162 is disposed. In an embodiment, in a plan view, the spacer 170 may be positioned inside one first pixel defining layer 162 among the plurality of first pixel defining layers 162. In a plan view, the one first pixel defining layer 162 may surround the spacer 170. For example, as illustrated in FIG. 5, a portion (e.g., a lower portion) of an outer side surface of the spacer 170 may contact an inner side surface of the one first pixel defining layer 162.

In an embodiment, both the spacer 170 and the first pixel defining layer 162 may be disposed directly on the third insulating layer 150. For example, as illustrated in FIG. 5, a lower surface of the spacer 170 and a lower surface of the first pixel defining layer 162 may contact an upper surface of the third insulating layer 150. That is, the lower surface of the spacer 170 and the lower surface of the first pixel defining layer 162 may be on substantially the same plane.

A thickness of the spacer 170 may be greater than a sum of a thicknesses of the first pixel defining layer 162 and a thickness of the second pixel defining layer 164. For example, a distance d1 between the upper surface of the third insulating layer 150 and an upper surface of the spacer 170 in the first non-emission area NEA1 may be greater than a distance d2 between the upper surface of the third insulating layer 150 and an upper surface of the second pixel defining layer 164 in the third non-emission area NEA3. In other words, a level of the upper surface of the spacer 170 may be higher than a level of the upper surface of the pixel defining layer 160.

In the first non-emission area NEA1 where the spacer 170 is disposed, one of the first to third emission layers EL1, EL2, and EL3 may be disposed around the spacer 170. In an embodiment, when the spacer 170 is disposed between two first pixel electrodes PE1 disposed adjacent to each other in the second direction DR2, the first emission layer EL1 may be disposed around the spacer 170. In an embodiment, when the spacer 170 is disposed between two second pixel electrodes PE2 disposed adjacent to each other in the second direction DR2, the second emission layer EL2 may be disposed around the spacer 170. In an embodiment, when the spacer 170 is disposed between two third pixel electrodes PE3 disposed adjacent to each other in the second direction DR2, the third emission layer EL3 may be disposed around the spacer 170. Hereinafter, an embodiment in which the first emission layer EL1 is disposed around the spacer 170 as illustrated in FIG. 5 will be described.

In a plan view, the spacer 170 may be positioned inside the first emission layer EL1. In a plan view, the first emission layer EL1 may surround the spacer 170. For example, a portion (e.g., a middle portion) of the outer side surface of the spacer 170 may contact an inner side surface of the first emission layer EL1.

The common electrode CE may cover the pixel defining layer 160, the first to third emission layers EL1, EL2, and EL3, and the spacer 170. For example, the common electrode CE may contact a portion (e.g., an upper portion) of the outer side surface of the spacer 170 and the upper surface of the spacer 170.

Referring to FIGS. 2 and 6, in an embodiment, an auxiliary electrode AUE may be disposed under the third insulating layer 150. The auxiliary electrode AUE may include a conductive material. In an embodiment, the auxiliary electrode AUE may be disposed on the second insulating layer 140, and may be disposed on the same layer as the source electrode SE and the drain electrode DE. In an embodiment, the auxiliary electrode AUE may be disposed on the first insulating layer 130, and may be disposed on the same layer as the gate electrode GE.

In an embodiment, the auxiliary electrode AUE may be disposed in the non-emission area NEA of the display area DA. For example, the auxiliary electrode AUE may extend in the first direction DR1, and may overlap the first pixel defining layer 162. The auxiliary electrode AUE may be disposed between two pixel electrodes disposed adjacent to each other in the second direction DR2.

Although only one auxiliary electrode AUE is illustrated in FIG. 2, the plurality of auxiliary electrodes AUE may be provided. In this case, the plurality of auxiliary electrodes AUE may be disposed to overlap different first pixel defining layers 162, respectively.

The auxiliary electrode contact portion ACP may be disposed in the non-emission area NEA of the display area DA. In an embodiment, the auxiliary electrode contact portion ACP may be disposed in some of the first non-emission areas NEA1, and is not disposed in the second non-emission areas NEA2 and third non-emission areas NEA3. The common electrode CE may be electrically connected to the auxiliary electrode AUE through the auxiliary electrode contact portion ACP. Accordingly, IR drop of a voltage (e.g., a low power voltage (“ELVSS”)) applied to the common electrode CE may be prevented or reduced.

In an embodiment, the plurality of auxiliary electrode contact portions ACP may overlap each of the auxiliary electrodes AUE. FIG. 2 illustrates that three auxiliary electrode contact portions ACP, respectively corresponding to the first to third emission areas EA1, EA2, and EA3, are disposed to overlap the auxiliary electrode AUE, but this is an example and embodiments are not limited thereto. As described above, since the common electrode CE is entirely disposed in the display area DA, in an embodiment, it may be sufficient to dispose one auxiliary electrode contact portion ACP per predetermined area (e.g., one auxiliary electrode contact portion ACP per about 1 mm²).

As illustrated in FIG. 2, each of the auxiliary electrode contact portions ACP may be disposed between two second pixel defining layers 164 disposed adjacent to each other in the first direction DR1 and between two pixel electrodes disposed adjacent to each other in the second direction DR2. In a plan view, the auxiliary electrode contact portion ACP may be spaced apart from each of the adjacent second pixel defining layers 164. In an embodiment, the auxiliary electrode contact portion ACP may be disposed between two first pixel electrodes PE1 disposed adjacent to each other in the second direction DR2. In a plan view, the auxiliary electrode contact portion ACP may be spaced apart from each of the adjacent first pixel electrodes PE1. In an embodiment, the auxiliary electrode contact portion ACP may be disposed between two second pixel electrodes PE2 disposed adjacent to each other in the second direction DR2 or between two third pixel electrodes PE3 disposed adjacent to each other in the second direction DR2.

The spacer 170 and the auxiliary electrode contact portion ACP may be disposed in different first non-emission areas NEA1, respectively. The auxiliary electrode contact portion ACP may be spaced apart from the spacer 170 with at least one pixel electrode or at least one second pixel defining layer 164 interposed therebetween.

In the first non-emission area NEA1 where the auxiliary electrode contact portion ACP is disposed, one of the first to third emission layers EL1, EL2, and EL3 may be disposed around the auxiliary electrode contact portion ACP. In an embodiment, when the auxiliary electrode contact portion ACP is disposed between two first pixel electrodes PE1 disposed adjacent to each other in the second direction DR2, the first emission layer EL1 may be disposed around the auxiliary electrode contact portion ACP. In an embodiment, when the auxiliary electrode contact portion ACP is disposed between two second pixel electrodes PE2 disposed adjacent to each other in the second direction DR2, the second emission layer EL2 may be disposed around the auxiliary electrode contact portion ACP. In an embodiment, when the auxiliary electrode contact portion ACP is disposed between two third pixel electrodes PE3 disposed adjacent to each other in the second direction DR2, the third emission layer EL3 may be disposed around the auxiliary electrode contact portion ACP. Hereinafter, an embodiment in which the second emission layer EL2 is disposed around the auxiliary electrode contact portion ACP as illustrated in FIG. 6 will be described.

In a plan view, the auxiliary electrode contact portion ACP may be positioned inside the second emission layer EL2. The auxiliary electrode contact portion ACP may include an auxiliary electrode contact hole CH and a first dam DM1. The auxiliary electrode contact hole CH may be defined in at least one insulating layer and the first pixel defining layer 162, which are on the auxiliary electrode AUE, to expose a portion of an upper surface of the auxiliary electrode AUE. For example, the auxiliary electrode contact hole CH may penetrate one first pixel defining layer 162 among the first pixel defining layers 162 and the third insulating layer 150 in the third direction DR3.

The first dam DM1 may be disposed on the first pixel defining layer 162 where the auxiliary electrode contact hole CH is defined. The first dam DM1 may surround the auxiliary electrode contact hole CH in a plan view. For example, the first dam DM1 may have a ring shape in a plan view.

In an embodiment, the first dam DM1 may be disposed on the same layer as the second pixel defining layer 164 and may include the same material as the second pixel defining layer 164. For example, a thickness of the first dam DM1 may be substantially the same as the thickness of the second pixel defining layer 164. The first dam DM1 may be substantially simultaneously formed with the second pixel defining layer 164.

In a plan view, the first dam DM1 may be positioned inside the second emission layer EL2. The first dam DM1 may prevent the second emission layer EL2 from flowing into the auxiliary electrode contact hole CH during formation of the second emission layer EL2 around the auxiliary electrode contact hole CH. That is, in a plan view, in an embodiment, the second emission layer EL2 may be disposed outside the first dam DM1 and is not disposed inside the first dam DM1. In a plan view, the second emission layer EL2 may surround the first dam DM1. For example, as illustrated in FIG. 6, a portion (e.g., a lower portion) of an outer side surface of the first dam DM1 may contact an inner side surface of the second emission layer EL2.

The common electrode CE may cover the pixel defining layer 160, the first to third emission layers EL1, EL2, and EL3, and the first dam DM1. For example, the common electrode CE may contact a portion (e.g., an upper portion) of the outer side surface of the first dam DM1 and an upper surface of the first dam DM1.

Referring to FIGS. 2 and 7, in an embodiment, the thickness measurement portion TMP may be disposed in the non-emission area NEA of the display area DA. In an embodiment, the thickness measurement portion TMP may be disposed in some of the first non-emission areas NEA1, and is not disposed in the second non-emission areas NEA2 and third non-emission areas NEA3.

The thickness measurement portion TMP may be disposed between two second pixel defining layers 164 disposed adjacent to each other in the first direction DR1 and between two pixel electrodes disposed adjacent to each other in the second direction DR2. In a plan view, the thickness measurement portion TMP may be spaced apart from each of the adjacent second pixel defining layers 164. In an embodiment, as illustrated in FIG. 2, the thickness measurement portion TMP may be disposed between two third pixel electrodes PE3 disposed adjacent to each other in the second direction DR2. In a plan view, the thickness measurement portion TMP may be spaced apart from each of the adjacent third pixel electrodes PE3. In an embodiment, the thickness measurement portion TMP may be disposed between two first pixel electrodes PE1 disposed adjacent to each other in the second direction DR2 or between two second pixel electrodes PE2 disposed adjacent to each other in the second direction DR2.

The spacer 170 and the thickness measurement portion TMP may be disposed in different first non-emission areas NEA1, respectively. The thickness measurement portion TMP may be spaced apart from the spacer 170 with at least one pixel electrode or at least one second pixel defining layer 164 interposed therebetween. Likewise, the auxiliary electrode contact portion ACP and the thickness measurement portion TMP may be disposed in different first non-emission areas NEA1, respectively. The thickness measurement portion TMP may be spaced apart from the auxiliary electrode contact portion ACP with at least one pixel electrode or at least one second pixel defining layer 164 interposed therebetween.

In the first non-emission area NEA1 where the thickness measurement portion TMP is disposed, one of the first to third emission layers EL1, EL2, and EL3 may be disposed around the thickness measurement portion TMP. In an embodiment, when the thickness measurement portion TMP is disposed between two first pixel electrodes PE1 disposed adjacent to each other in the second direction DR2, the first emission layer EL1 may be disposed around the thickness measurement portion TMP. In an embodiment, when the thickness measurement portion TMP is disposed between two second pixel electrodes PE2 disposed adjacent to each other in the second direction DR2, the second emission layer EL2 may be disposed around the thickness measurement portion TMP. In an embodiment, when the thickness measurement portion TMP is disposed between two third pixel electrodes PE3 disposed adjacent to each other in the second direction DR2, the third emission layer EL3 may be disposed around the thickness measurement portion TMP. Hereinafter, an embodiment in which the third emission layer EL3 is disposed around the thickness measurement portion TMP as illustrated in FIG. 7 will be described.

In a plan view, the thickness measurement portion TMP may be positioned inside the third emission layer EL3. The thickness measurement portion TMP may include a through hole TH and a second dam DM2. The through hole TH may be defined in the first pixel defining layer 162 to expose a portion of the upper surface of the third insulating layer 150. For example, the through hole TH may penetrate one first pixel defining layer 162 among the first pixel defining layers 162 in the third direction DR3.

The second dam DM2 may be disposed on the first pixel defining layer 162 where the through hole TH is defined. The second dam DM2 may surround the through hole TH in a plan view. For example, the second dam DM2 may have a ring shape in a plan view.

In an embodiment, the second dam DM2 may be disposed on the same layer as the second pixel defining layer 164 and may include the same material as the second pixel defining layer 164. For example, a thickness of the second dam DM2 may be substantially the same as the thickness of the second pixel defining layer 164. The second dam DM2 may be substantially simultaneously formed with the second pixel defining layer 164.

In a plan view, the second dam DM2 may be positioned inside the third emission layer EL3. The second dam DM2 may prevent the third emission layer EL3 from flowing into the through hole TH during formation of the third emission layer EL3 around the through hole TH. That is, in a plan view, in an embodiment, the third emission layer EL3 may be disposed outside the second dam DM2 and is not disposed inside the second dam DM2. In a plan view, the third emission layer EL3 may surround the second dam DM2. For example, as illustrated in FIG. 7, a portion (e.g., a lower portion) of an outer side surface of the second dam DM2 may contact an inner side surface of the third emission layer EL3. During a manufacturing process of the display device 10, a thickness of the third emission layer EL3 formed by inkjet printing can be measured using an inner space of the second dam DM2 and the through hole TH.

The common electrode CE may cover the pixel defining layer 160, the first to third emission layers EL1, EL2, and EL3, and the second dam DM2. For example, the common electrode CE may contact a portion (e.g., an upper portion) of the outer side surface of the second dam DM2 and an upper surface of the second dam DM2.

As described above, according to embodiments, the structures, such as the spacer 170, the auxiliary electrode contact portion ACP, or the thickness measurement portion TMP, are not disposed in the second and third non-emission areas NEA2 and NEA3 and may be disposed only in the first non-emission areas NEA1, so that the width of each of the second and third non-emission areas NEA2 and NEA3 in the first direction DR1 may be reduced. That is, since the structures do not overlap each of the second pixel defining layers 164, the width of each of the second pixel defining layers 164 in the first direction DR1 may be further reduced. Accordingly, a high resolution display device 10 having improved display quality may be implemented according to embodiments of the present invention.

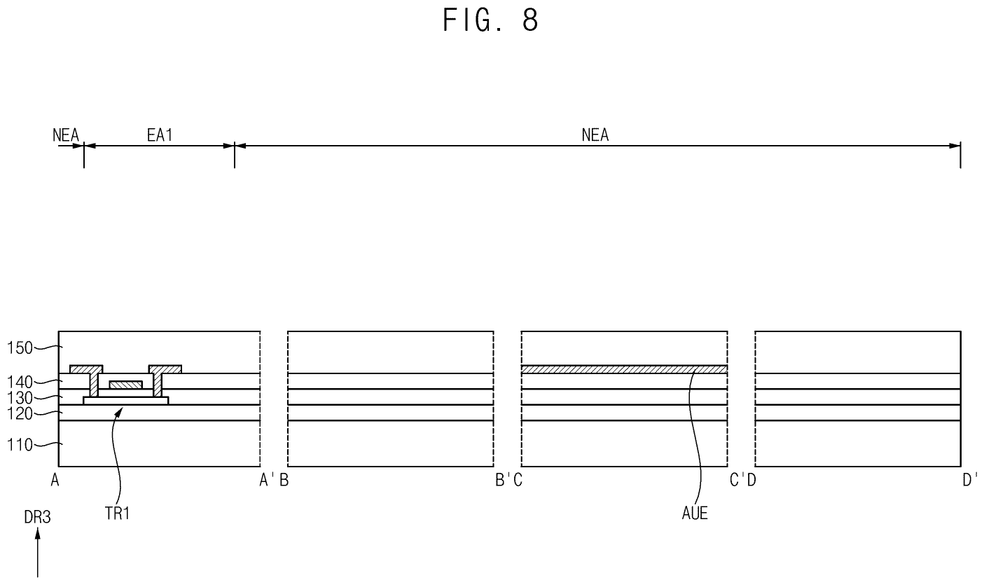

FIGS. 8 to 18 are cross-sectional views illustrating a method of manufacturing a display device according to an embodiment.

FIGS. 8 to 18 illustrate a manufacturing method of the display device 10 described with reference to FIGS. 1 to 7. In each of FIGS. 8 to 18, an A-A′ cross-sectional view corresponds to a left portion of the cross-sectional view of FIG. 3, a B-B′ cross-sectional view corresponds to the cross-sectional view of FIG. 5, a C-C′ cross-sectional view corresponds to the cross-sectional view of FIG. 6, and a D-D′ cross-sectional view corresponds to the cross-sectional view of FIG. 7. Hereinafter, for convenience of explanation, a further detailed description of elements and technical aspects previously described with reference to FIGS. 2 to 7 may be omitted or simplified.

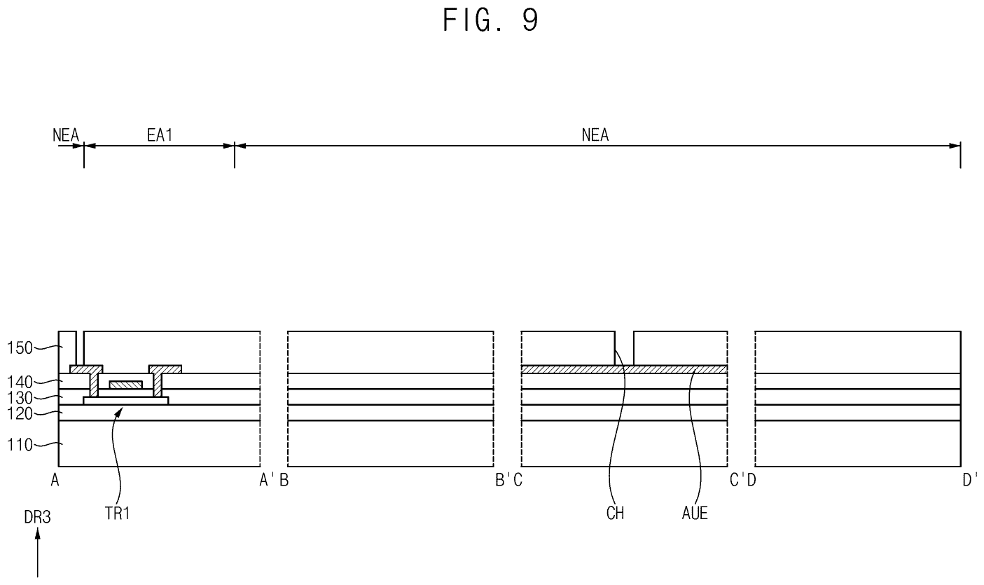

Referring to FIG. 8, the buffer layer 120, the first insulating layer 130, the second insulating layer 140, the first thin film transistor TR1, and the auxiliary electrode AUE may be formed on the substrate 110. The auxiliary electrode AUE may be formed in the non-emission area NEA. The third insulating layer 150 may be formed on the second insulating layer 140 and may cover the first thin film transistor TR1 and the auxiliary electrode AUE. The third insulating layer 150 may be formed by providing an organic insulating material on the second insulating layer 140. Referring to FIG. 9, the first contact hole and the auxiliary electrode contact hole CH may be formed in the third insulating layer 150. For example, a photoresist pattern may be formed on the third insulating layer 150, and the first contact hole and the auxiliary electrode contact hole CH may be formed by etching the third insulating layer 150 using the photoresist pattern as an etch mask. The first contact hole may expose a portion of an upper surface of the drain electrode of the first thin film transistor TR1. The auxiliary electrode contact hole CH may expose a portion of an upper surface of the auxiliary electrode AUE.

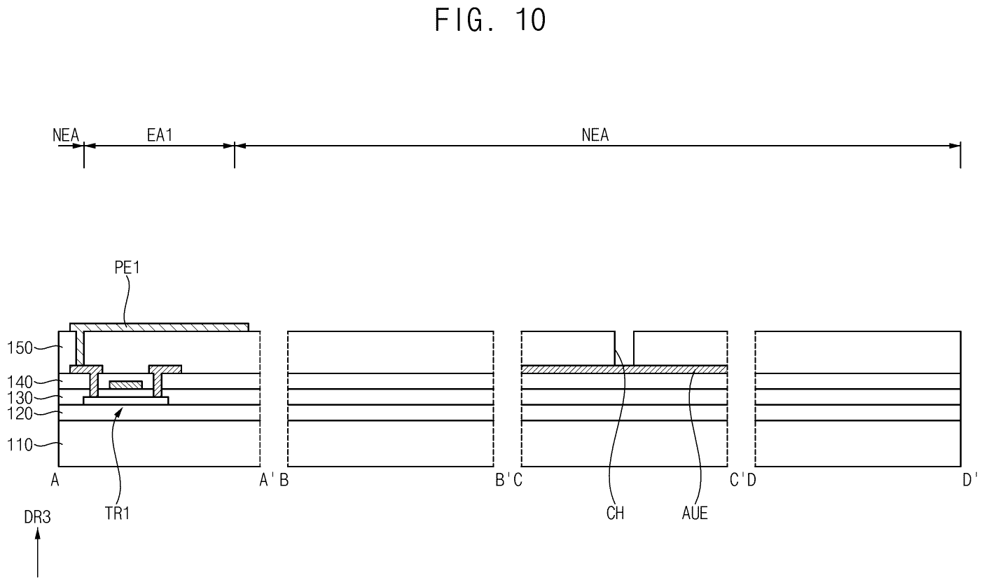

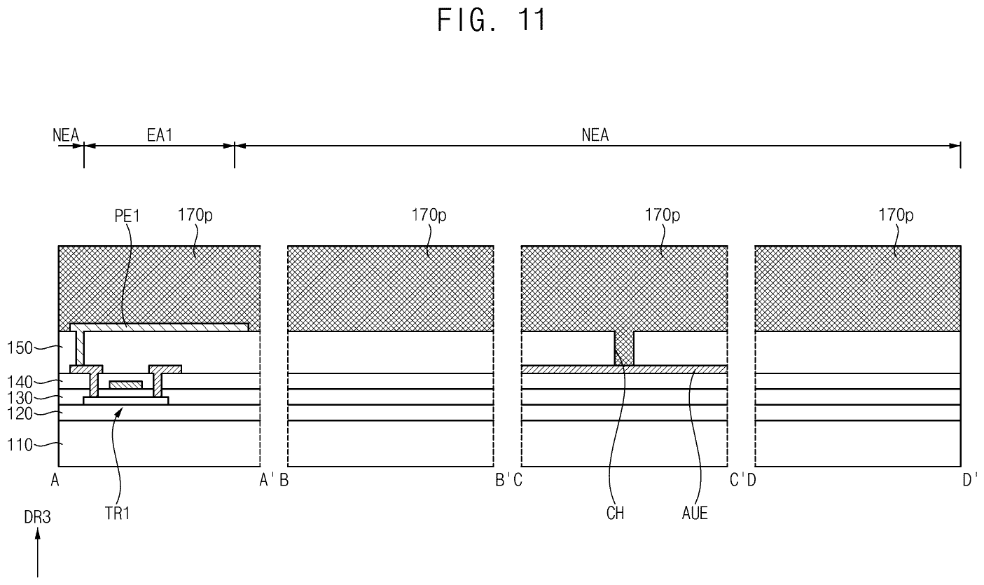

Referring to FIG. 10, the first pixel electrode PE1 may be formed in the first emission area EA1 on the third insulating layer 150. For example, a preliminary conductive layer may be formed on the third insulating layer 150, and the preliminary conductive layer may be patterned to form the first pixel electrode PE1. The first pixel electrode PE1 may be electrically connected to the drain electrode of the first thin film transistor TR1 through the first contact hole.

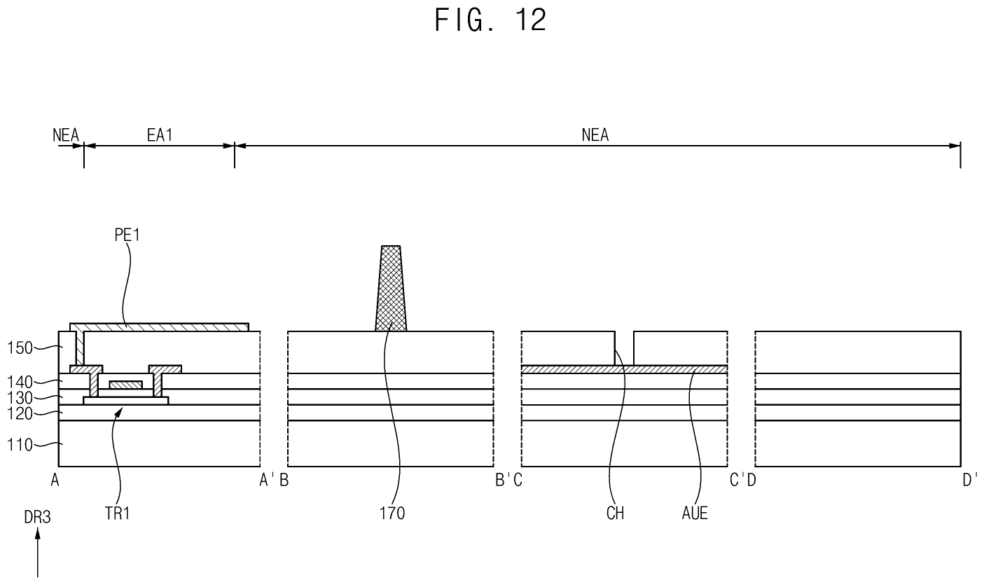

Referring to FIGS. 11 and 12, the spacer 170 may be formed in the non-emission area NEA on the third insulating layer 150. The spacer 170 may be formed in some of the first non-emission areas NEA1 of FIG. 2.

First, as illustrated in FIG. 11, a first photoresist layer 170p may be formed on the third insulating layer 150 and the first pixel electrode PE1. Subsequently, as illustrated in FIG. 12, the spacer 170 may be formed by patterning the first photoresist layer 170p through an exposure and development process using a first photomask. For example, the first photoresist layer 170p may include positive type photoresist. When the first photoresist layer 170p is developed, a portion of the first photoresist layer 170p corresponding to a light blocking portion of the first photomask may remain to form the spacer 170, and the other portion of the first photoresist layer 170p corresponding to a light transmitting portion of the first photomask may be removed.

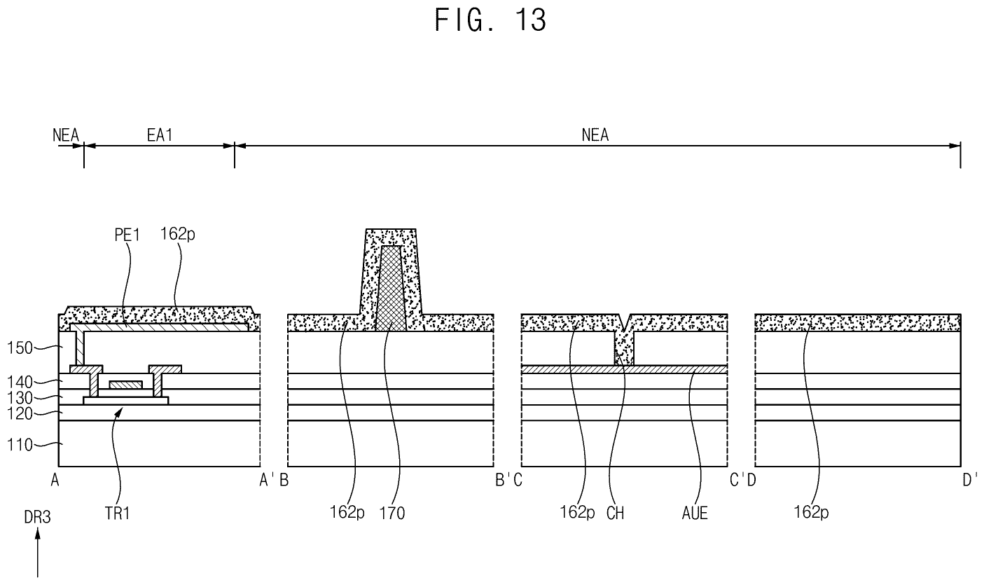

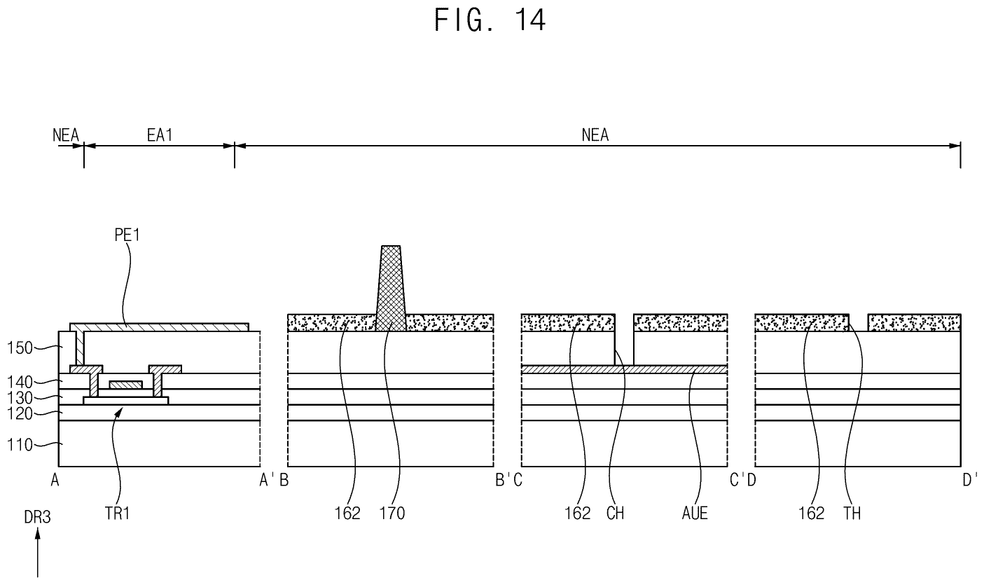

Referring to FIGS. 13 and 14, the first pixel defining layers 162 may be formed on the third insulating layer 150 and the spacer 170. As illustrated in FIG. 2, each of the first pixel defining layers 162 may extend in the first direction DR1, and the first pixel defining layers 162 may be spaced apart from each other in the second direction DR2.

First, as illustrated in FIG. 13, a second photoresist layer 162p may be formed on the third insulating layer 150, the first pixel electrode PE1, and the spacer 170. The second photoresist layer 162p may cover the spacer 170. A thickness of the second photoresist layer 162p may be less than a thickness of the first photoresist layer 170p.

Subsequently, as illustrated in FIG. 14, the first pixel defining layers 162 may be formed by patterning the second photoresist layer 162p through an exposure and development process using a second photomask. For example, the second photoresist layer 162p may include positive type photoresist. When the second photoresist layer 162p is developed, a portion of the second photoresist layer 162p corresponding to a light blocking portion of the second photomask may remain to form the first pixel defining layers 162, and the other portion of the second photoresist layer 162p corresponding to a light transmitting portion of the second photomask may be removed.

Referring again to FIG. 2, portions of the second photoresist layer 162p overlapping the first and third non-emission areas NEA1 and NEA3 may remain to form the first pixel defining layers 162, and portions of the second photoresist layer 162p overlapping the first to third emission areas EA1, EA2, and EA3 and the second non-emission areas NEA2 may be removed.

In the some of the first non-emission areas NEA1 where the spacer 170 is formed, a portion of the second photoresist layer 162p overlapping the spacer 170 may be removed (refer to B-B′ of FIG. 14). That is, the first pixel defining layer 162 may surround the spacer 170 in a plan view.

In some of the first non-emission area NEA1 where the auxiliary electrode AUE is formed, a portion of the second photoresist layer 162p overlapping the auxiliary electrode contact hole CH formed in the third insulating layer 150 may be removed (refer to C-C′ of FIG. 14). That is, the auxiliary electrode contact hole CH may penetrate the first pixel defining layer 162 and the third insulating layer 150 in the third direction DR3. The auxiliary electrode contact hole CH may expose a portion of the upper surface of the auxiliary electrode AUE.

In some of the first non-emission area NEA1 where the spacer 170 and the auxiliary electrode contact hole CH are not formed, a portion of the second photoresist layer 162p may be removed to form the through hole TH (refer to D-D′ in FIG. 14). The through hole TH may be defined in the first pixel defining layer 162 to expose a portion of the upper surface of the third insulating layer 150.

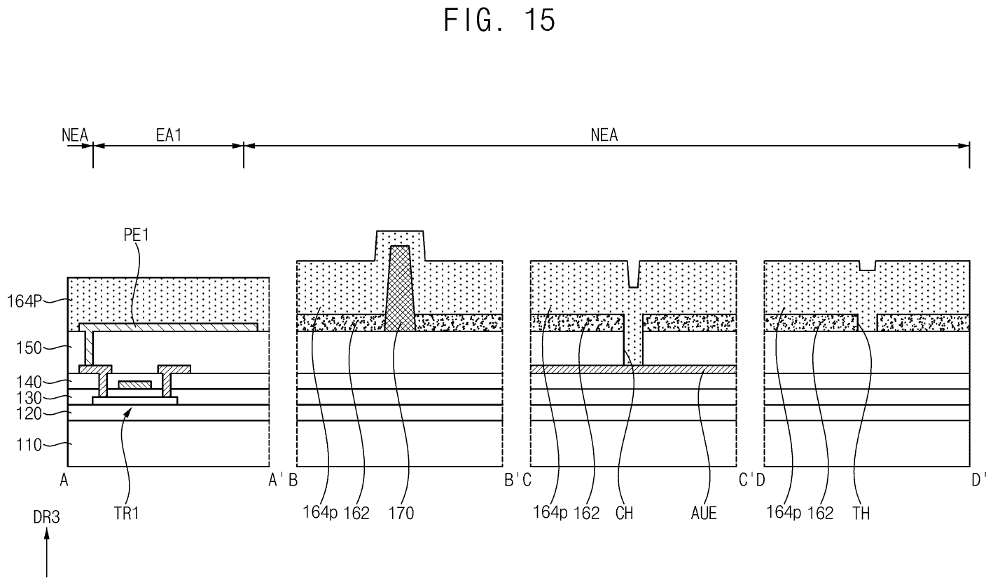

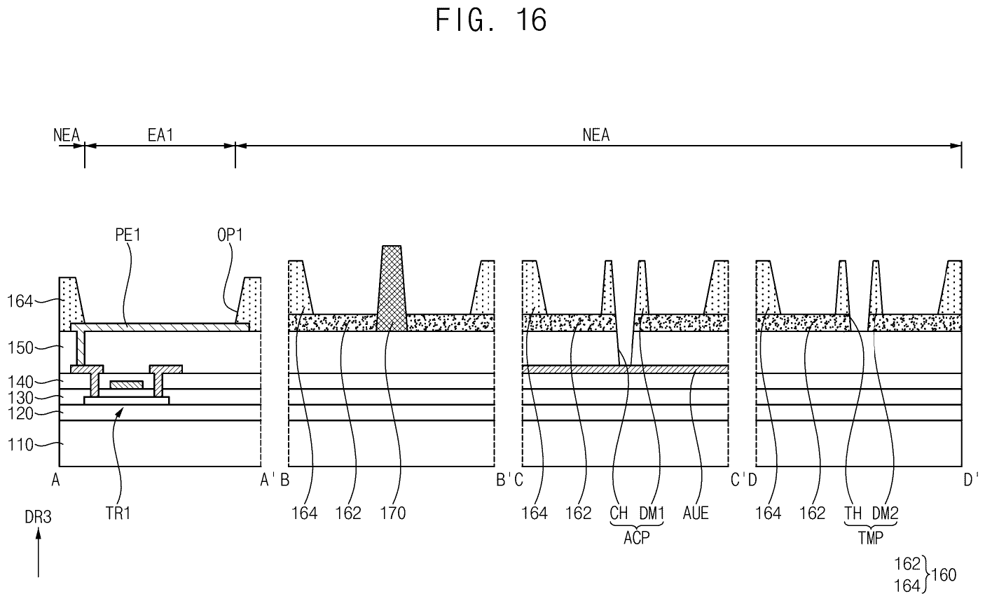

Referring to FIGS. 15 and 16, the second pixel defining layers 164, the first dam DM1, and the second dam DM2 may be formed on the third insulating layer 150 and the first pixel defining layers 162. As illustrated in FIG. 2, each of the second pixel defining layers 164 may extend in the second direction DR2, and the second pixel defining layers 164 may be spaced apart from each other in the first direction DR1.

First, as illustrated in FIG. 15, a third photoresist layer 164p may be formed on the third insulating layer 150, the first pixel electrode PE1, the spacer 170, and the first pixel defining layers 162. A thickness of the third photoresist layer 164p may be less than a thickness of the first photoresist layer 170p. A sum of the thicknesses of the second photoresist layer 162p and the thickness of the third photoresist layer 164p may be less than the thickness of the first photoresist layer 170p.

Subsequently, as illustrated in FIG. 16, the second pixel defining layers 164, the first dam DM1, and the second dam DM2 may be formed by patterning the third photoresist layer 164p through an exposure and development process using a third photomask. For example, the third photoresist layer 164p may include positive type photoresist. When the third photoresist layer 164p is developed, a portion of the third photoresist layer 164p corresponding to a light blocking portion of the third photomask may remain to form the second pixel defining layers 164, the first dam DM1, and the second dam DM2, and the other portion of the third photoresist layer 164p corresponding to a light transmitting portion of the third photomask may be removed.

Referring further to FIG. 2, portions of the third photoresist layer 164p overlapping the second and third non-emission areas NEA2 and NEA3 may remain to form the second pixel defining layers 164, and portions of the third photoresist layer 164p overlapping the first to third emission areas EA1, EA2, and EA3 and the first non-emission areas NEA1 may be removed.

In an embodiment, the third photoresist layer 164p may include a liquid repellent material. The liquid repellent material may include a fluorine-based material. During formation of the third photoresist layer 164p, the liquid repellent material may be concentrated in a portion of the third photoresist layer 164p adjacent to an upper surface of the third photoresist layer 164p. Accordingly, an upper surface of each of the second pixel defining layers 164 may have liquid repellency.

If the spacer 170 is formed after the second pixel defining layers 164 are formed, the liquid repellency of the upper surface of each of the second pixel defining layers 164 may disappear due to the exposure and development process for forming the spacer 170. Accordingly, the spacer 170 may be formed before the second pixel defining layers 164 are formed.

In some of the first non-emission area NEA1 where the spacer 170 is formed, the third photoresist layer 164p may be entirely removed (refer to B-B′ in FIG. 16).

In some of the first non-emission area NEA1 where the auxiliary electrode contact hole CH is formed, a portion of the third photoresist layer 164p, which surrounds the auxiliary electrode contact hole CH in a plan view, may remain to form the first dam DM1, and the other portion of the third photoresist layer 164p may be removed (refer to C-C′ in FIG. 16).

In some of the first non-emission area NEA1 where the through hole TH is formed, a portion of the third photoresist layer 164p, which surrounds the through hole TH in a plan view, may remain to form the second dam DM2, and the other portion of the third photoresist layer 164p may be removed (refer to D-D′ in FIG. 16).

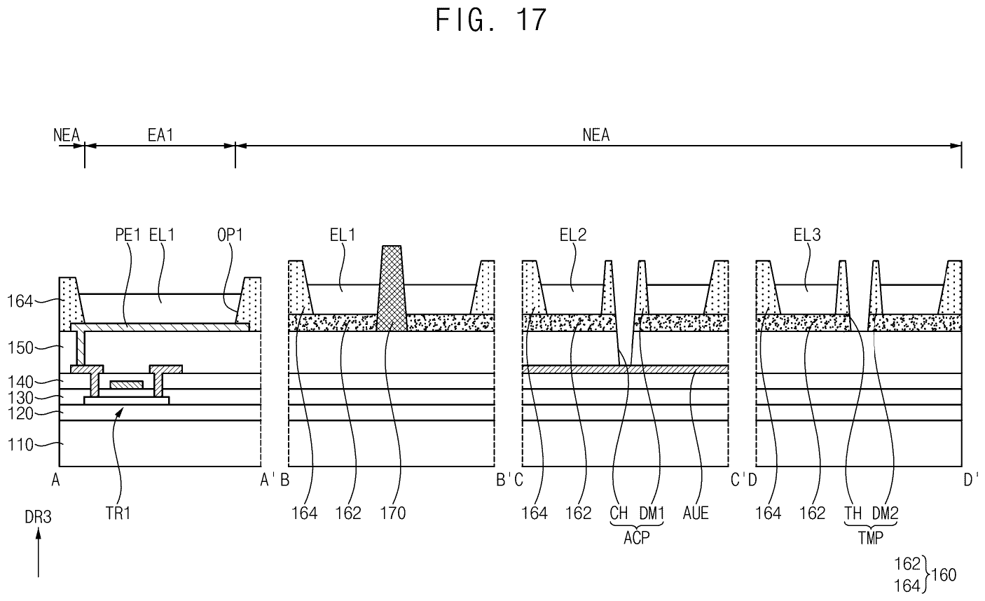

Referring to FIG. 17, the first to third emission layers EL1, EL2, and EL3 may be formed. The first to third emission layers EL1, EL2, and EL3 may be formed by inkjet printing.

Referring again to FIG. 2, each of the first to third emission layers EL1, EL2, and EL3 may extend in the second direction DR2. That is, each of the first emission layers EL1 may overlap the plurality of first pixel electrodes PE1 spaced apart from each other in the second direction DR2 and the plurality of first non-emission areas NEA1 spaced apart from each other in the second direction DR2. Each of the second emission layers EL2 may overlap the plurality of second pixel electrodes PE2 spaced apart from each other in the second direction DR2 and the plurality of first non-emission areas NEA1 spaced apart from each other in the second direction DR2. Each of the third emission layers EL3 may overlap the plurality of third pixel electrodes PE3 spaced apart from each other in the second direction DR2 and the plurality of first non-emission areas NEA1 spaced apart from each other in the second direction DR2.

In some of the first non-emission area NEA1 where the spacer 170 is formed, one emission layer among the first to third emission layers EL1, EL2, and EL3 (e.g., the first emission layer EL1) may be disposed outside the spacer 170 (refer to B-B′ in FIG. 17).

In some of the first non-emission area NEA1 where the auxiliary electrode contact hole CH is formed, one emission layer among the first to third emission layers EL1, EL2, and EL3 (e.g., the second emission layer EL2) may be disposed outside the first dam DM1 (refer to C-C′ in FIG. 17). The one emission layer may not flow into the auxiliary electrode contact hole CH, which penetrates the third insulating layer 150 and the first pixel defining layer 162, due to the first dam DM1.

In some of the first non-emission area NEA1 where the through hole TH is formed, one emission layer among the first to third emission layers EL1, EL2, and EL3 (e.g., the third emission layer EL3) may be disposed outside of the second dam DM2 (refer to D-D′ in FIG. 17). The one emission layer may not flow into the through hole TH, which penetrates the first pixel defining layer 162, due to the second dam DM2. In addition, a thickness of the one emission layer can be measured using the through hole TH.

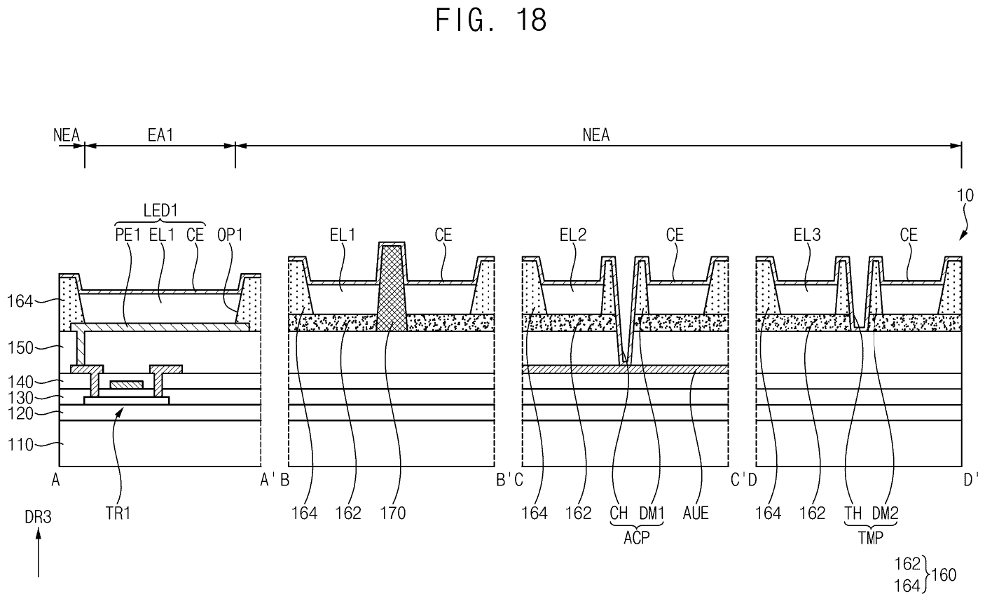

Referring to FIG. 18, the common electrode CE may be formed on the pixel defining layer 160, the first to third emission layers EL1, EL2, and EL3, the spacer 170, the first dam DM1, and the second dam DM2. For example, the common electrode CE may be entirely formed in the first to third emission areas EA1, EA2, and EA3 and the non-emission area NEA.

In some of the first non-emission area NEA1 where the auxiliary electrode contact hole CH is formed, the common electrode CE may be electrically connected to the auxiliary electrode AUE through the auxiliary electrode contact hole CH. Accordingly, embodiments may prevent or reduce IR drop of a voltage (e.g., a low power voltage (“ELVSS”)) applied to the common electrode CE.

As described above, according to embodiments, the structures, such as the spacer 170, the auxiliary electrode contact portion ACP, or the thickness measurement portion TMP, are not disposed in the second and third non-emission areas NEA2 and NEA3, and may instead be disposed only in the first non-emission areas NEA1. As a result, the width of each of the second and third non-emission areas NEA2 and NEA3 in the first direction DR1 may be reduced. That is, since the structures do not overlap each of the second pixel defining layers 164, the width of each of the second pixel defining layers 164 in the first direction DR1 may be further reduced. Accordingly, a high resolution display device 10 having improved display quality may be implemented.

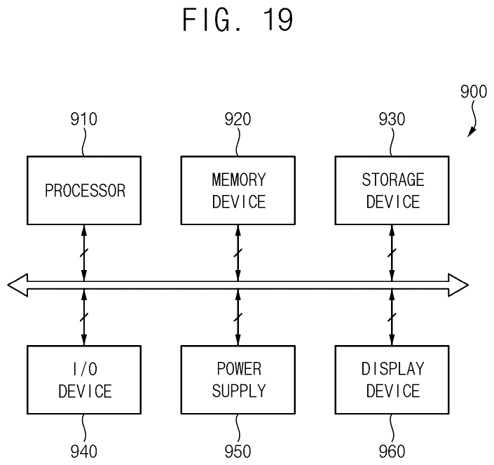

FIG. 19 is a block diagram illustrating an electronic device according to an embodiment.

Referring to FIG. 19, in an embodiment, an electronic device 900 may include a processor 910, a memory device 920, a storage device 930, an input/output (“I/O”) device 940, a power supply 950, and a display device 960. Here, the display device 960 may correspond to the display device 10 of FIG. 1. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments are not limited thereto, in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus. The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

While the present invention has been particularly shown and described with reference to embodiments thereof, it will be understood by those of ordinary skill in the art that various changes in form and detail may be made therein without departing from the spirit and scope of the present invention as defined by the following claims.

What is claimed is:

1. A display device, comprising:
a plurality of thin film transistors;
an insulating layer disposed on the thin film transistors and including an organic insulating material;
a plurality of pixel electrodes disposed on the insulating layer, respectively electrically connected to the thin film transistors, and disposed in a first direction and a second direction crossing the first direction;
a pixel defining layer disposed on the insulating layer and the pixel electrodes, exposing a central portion of each of the pixel electrodes, covering a peripheral portion of each of the pixel electrodes, and including:
a plurality of first pixel defining layers extending in the first direction and spaced apart from each other in the second direction; and
a plurality of second pixel defining layers extending in the second direction and spaced apart from each other in the first direction; and
a spacer disposed on the insulating layer and disposed between two second pixel defining layers disposed adjacent to each other in the first direction among the second pixel defining layers and between two pixel electrodes disposed adjacent to each other in the second direction among the pixel electrodes.

2. The display device of claim 1, wherein in a plan view, the spacer is spaced apart from each of the second pixel defining layers.

3. The display device of claim 1, wherein in a plan view, the spacer is positioned inside one first pixel defining layer among the first pixel defining layers.

4. The display device of claim 3, wherein an outer side surface of the spacer contacts an inner side surface of the one first pixel defining layers.

5. The display device of claim 1, wherein a lower surface of the spacer and a lower surface of each of the first pixel defining layers contact an upper surface of the insulating layer.

6. The display device of claim 1, wherein a distance between an upper surface of the insulating layer and an upper surface of the spacer is greater than a distance between the upper surface of the insulating layer and an upper surface of each of the second pixel defining layers.

7. The display device of claim 1, further comprising:
a plurality of emission layers disposed on the pixel electrodes, extending in the second direction, and spaced apart from each other in the first direction; and
a common electrode disposed on the pixel electrodes, the pixel defining layer, and the emission layers,
wherein each of the emission layers is disposed between two second pixel defining layers disposed adjacent to each other in the first direction.

8. The display device of claim 7, wherein
the emission layers include a first emission layer, a second emission layer, and a third emission layer, and
the first emission layer, the second emission layer, and the third emission layer emit light of different colors and are sequentially arranged in the first direction.

9. The display device of claim 7, wherein in a plan view, the spacer is positioned inside one emission layer among the emission layers.

10. The display device of claim 9, wherein an outer side surface of the spacer contacts an inner side surface of the one emission layer.

11. The display device of claim 7, further comprising:
an auxiliary electrode disposed under the insulating layer and overlapping one first pixel defining layer among the first pixel defining layers,
wherein the common electrode is electrically connected to the auxiliary electrode through a contact hole penetrating the insulating layer and the one first pixel defining layer.

12. The display device of claim 11, further comprising:
a dam disposed on the one first pixel defining layer and surrounding the contact hole in a plan view.

13. The display device of claim 12, wherein in the plan view,
the dam is positioned inside one emission layer among the emission layers, and
the one emission layer is disposed outside the dam and is not disposed inside the dam.

14. The display device of claim 13, wherein an outer side surface of the dam contacts an inner side surface of the one emission layer.

15. The display device of claim 12, wherein in the plan view, the dam is spaced apart from the spacer with at least one pixel electrode among the pixel electrodes or at least one second pixel defining layer among the second pixel defining layers interposed therebetween.

16. The display device of claim 7, wherein a through hole is defined that penetrates one first pixel defining layer among the first pixel defining layers and exposes an upper surface of the insulating layer, and the display device further comprises:
a dam disposed on the one first pixel defining layer and surrounding the through hole in a plan view.

17. The display device of claim 16, wherein in the plan view, the dam is spaced apart from the spacer with at least one pixel electrode among the pixel electrodes or at least one second pixel defining layer among the second pixel defining layers interposed therebetween.

18. A display device, comprising:
a plurality of thin film transistors;
an insulating layer disposed on the thin film transistors and including an organic insulating material;
a plurality of pixel electrodes disposed on the insulating layer, respectively electrically connected to the thin film transistors, and disposed in a first direction and a second direction crossing the first direction;
a pixel defining layer disposed on the insulating layer and the pixel electrodes, exposing a central portion of each of the pixel electrodes, covering a peripheral portion of each of the pixel electrodes, and including:
a plurality of first pixel defining layers extending in the first direction and spaced apart from each other in the second direction; and
a plurality of second pixel defining layers extending in the second direction and spaced apart from each other in the first direction;
an auxiliary electrode disposed under the insulating layer and overlapping one first pixel defining layer among the first pixel defining layers;
a plurality of emission layers disposed on the pixel electrodes, extending in the second direction, and spaced apart from each other in the first direction; and
a common electrode disposed on the pixel electrodes, the pixel defining layer, and the emission layers and electrically connected to the auxiliary electrode through a contact hole penetrating the insulating layer and the one first pixel defining layer.

19. The display device of claim 18, further comprising:
a dam disposed on the one first pixel defining layer and surrounding the contact hole in a plan view.

20. A display device, comprising:
a plurality of thin film transistors;
an insulating layer disposed on the thin film transistors and including an organic insulating material;
a plurality of pixel electrodes disposed on the insulating layer, respectively electrically connected to the thin film transistors, and disposed in a first direction and a second direction crossing the first direction;
a pixel defining layer disposed on the insulating layer and the pixel electrodes, exposing a central portion of each of the pixel electrodes, covering a peripheral portion of each of the pixel electrodes, and including:
a plurality of first pixel defining layers extending in the first direction and spaced apart from each other in the second direction; and
a plurality of second pixel defining layers extending in the second direction and spaced apart from each other in the first direction; and
a dam disposed on one first pixel defining layer among the first pixel defining layers and surrounding a through hole in a plan view, the through hole penetrating the one first pixel defining layer and exposing an upper surface of the insulating layer.

21. An electronic device, comprising:
a display device; and
a power supply configured to provide power to the display device,
wherein the display device comprises:
a plurality of thin film transistors;
an insulating layer disposed on the thin film transistors and including an organic insulating material;
a plurality of pixel electrodes disposed on the insulating layer, respectively electrically connected to the thin film transistors, and disposed in a first direction and a second direction crossing the first direction;
a pixel defining layer disposed on the insulating layer and the pixel electrodes, exposing a central portion of each of the pixel electrodes, covering a peripheral portion of each of the pixel electrodes, and including:
a plurality of first pixel defining layers extending in the first direction and spaced apart from each other in the second direction; and
a plurality of second pixel defining layers extending in the second direction and spaced apart from each other in the first direction; and
a spacer disposed on the insulating layer and disposed between two second pixel defining layers disposed adjacent to each other in the first direction among the second pixel defining layers and between two pixel electrodes disposed adjacent to each other in the second direction among the pixel electrodes.
